(19) United States
(12) Patent Application Publication
(10) Pub. No.: US 2013/0174898 A1
(43) Pub. Date: Jul. 11, 2013

(54) THIN-FILM SOLAR CELL AND MANUFACTURING METHOD THEREOF

(71) Applicant: Panasonic Corporation, Osaka (JP)

(72) Inventors: Mitsuo SAITOH, Osaka (JP); Hitoshi YAMANISHI, Osaka (JP); Hisao NAGAI, Osaka (JP); Tomohiro Okumura, Osaka (JP); Ichiro NAKAYAMA, Osaka (JP)

(73) Assignee: PANASONIC CORPORATION, Osaka (JP)

(21) Appl. No.: 13/722,115

(22) Filed: Dec. 20, 2012

(30) Foreign Application Priority Data
Dec. 21, 2011 (JP) 2011-279411
Nov. 28, 2012 (JP) 2012-259990

(51) Int. Cl. H01L 31/065; H01L 31/075

(52) U.S. Cl. CPC H01L 31/065; H01L 31/075
USPC 136/255; 438/87

(57) ABSTRACT

To improve the conversion efficiency of a thin film solar cell constituted by a pin junction-type thin film layer. Specifically, a thin film solar cell including a laminate which includes first diffusion layer made of semiconductor having p-type or n-type conductivity, a film-forming layer made of semiconductor having lower conductivity than the first diffusion layer, and second diffusion layer made of semiconductor having different polarity from the film-forming layer inside is provided. The first diffusion layer and the second diffusion layer have impurities distributed in a film-thickness direction with a concentration gradient.

This application is entitled to the benefits of Japanese Patent Application No. 2011-279411, filed on Dec. 21, 2011, and of Japanese Patent Application No. 2012-259990, filed on Nov. 28, 2012.

### TECHNICAL FIELD

The present invention relates to a thin film solar cell and a manufacturing method thereof.

### BACKGROUND ART

Crystalline silicon solar cells account for approximately 90% of the solar cell market due to their high conversion efficiency. However, still, a period of 15 years to 20 years is required for users to redeem the installation costs of crystalline silicon solar cells. Therefore, several attempts have been made to develop techniques regarding thin film solar cells and manufacturing methods thereof for the purpose of reducing the thickness of the silicon substrate as much as possible in order to reduce the costs for silicon materials which account for approximately 50% of the manufacturing costs.

Among such thin film solar cells, a thin film solar cell obtained by sequentially laminating film-forming layers mainly containing silicon using a thin film method, such as a CVD method, a sputtering method, or a vapor-deposition method, and forming desired semiconductor layers is known. The respective semiconductor layers can be formed to be extremely thin at a film thickness of several nm to several μm (refer to NPL 1 and 2).

Particularly, in thin film solar cells for which silicon (Si), silicon-germanium (SiGe), germanium (Ge), silicon carbide (SiC), or the like is used, it is difficult to form the thin films into a single crystal or a polycrystalline layer due to technical aspects regarding the thin film method. Therefore, in general, the thin film is constituted by an amorphous phase or a microcrystalline phase made of crystalline grains having a grain diameter of approximately 10 nm. However, the distance through which carriers can migrate in the amorphous phase or the microcrystalline phase (carrier diffusion length) is extremely small. Therefore, the thin film solar cell constitutes a pin junction-type solar cell constituted by a p-layer (a P-type semiconductor), an i-layer (an almost intrinsic semiconductor), and an n-layer (an N-type semiconductor), and does not constitute a PN junction-type solar cell which is often used in crystalline solar cells (refer to NPL 1 and 2).

Generally, the pin junction-type solar cell has three major configuration characteristics. The first characteristic is that the solar cell is formed in the order of pin or nip (the i-layer is located between the n-layer and the p-layer). The second characteristic is that the thicknesses of the p-layer and the n-layer are as extremely thin as several nm to several tens of nm, and the thickness of the i-layer is as relatively thick as several hundreds of nm to several μm. The third characteristic is that the p-layer and the n-layer are semiconductor layers having a high carrier density and a high conductivity, and the i-layer is a semiconductor layer having a low carrier density and a low conductivity.

The light absorption coefficient of the microcrystalline phase of silicon is different from the light absorption coefficient of the amorphous phase of silicon. Therefore, generally, the thickness of the i-layer made of an amorphous phase of silicon is set to approximately 200 nm to 400 nm, and the thickness of the i-layer made of a microcrystalline phase of silicon is set to approximately 2 μm to 4 μm.

It is known that the pin junction-type solar cell has a high built-in electric field formed of the p-layer and the n-layer, and the i-layer having a large carrier diffusion length occupies most of the carrier diffusion path, whereby it is easy to extract photocurrents even when the carrier diffusion length is small, and a high conversion efficiency at a several % level can be obtained. Therefore, the p-layer and the n-layer preferably have a high carrier density (approximately 1×10⁹ atoms/cm³ to 1×10²¹ atoms/cm³), and are preferably thin films (approximately 1 nm to 50 nm).

An example in which, in a pin junction-type solar cell formed of a high-density thin film, the p-layer and the n-layer are formed by laminating silicon layers made of an amorphous phase using a CVD method is described in PTL 1. Using FIG. 13, the pin junction-type solar cell described in PTL 1 will be described.

The pin junction-type solar cell shown in FIG. 13 includes Ag layer 102 formed using a sputtering method and ZnO transparent conductive layer 103 on band-shaped SUS substrate 101. On ZnO transparent conductive layer 103, n-type (or p-type) Si semiconductor layer 104 formed using a high-frequency plasma CVD method, first i-type semiconductor layer 105 formed using a microwave plasma CVD method, and second i-type semiconductor layer 106 formed using the high-frequency plasma DVD method are provided. Semiconductor layers 104 to 106 are formed in a film-forming apparatus in which a series of Si films can be formed. On second i-type semiconductor layer 106, p-type (n-type) Si semiconductor layer 107 formed using a plasma doping method is provided. Furthermore, ITO layer 108 is formed on p-type (n-type) semiconductor layer 107, and further an Ag electrode (not shown) is formed, in order to efficiently collect and extract electric current.

Furthermore, PTL 1 discloses an example in which first i-type silicon semiconductor layer 105 is formed of silicon-germanium instead of silicon. Furthermore, an example is described in which the content of H or the quality of a film in first i-type Si semiconductor layer 105 is changed by partitioning a Si film-forming chamber or a SiGe film-forming chamber in a film-forming apparatus, and changing the film-forming conditions. In any cases, the silicon semiconductor layer and the silicon-germanium semiconductor layer formed in the examples of PTL 1 are all formed of an amorphous phase.

A pin junction-type thin film solar cell in which the respective semiconductor layers (the p-layer, the i-layer, and the n-layer) are all film-forming layers formed using a gas phase method is known (refer to PTL 2 to 5).

A thin film solar cell including a film-forming layer formed using a gas phase method and a diffusion layer formed by diffusing impurities in the film-forming layer is known (PTL 6 and 7).

A thin film solar cell including a semiconductor layer formed using a coating method is known (PTL 8 and 9).

### CITATION LIST

### Patent Literature

PTL 1: Japanese Patent No. 3093504

PTL 2: Japanese Patent Application Laid-Open No. 2005-39252

PTL 3: U.S. Patent Application Laid-Open No. 2009/0272423

PTL 4: Japanese Patent Application Laid-Open No. SHO62-115785

PTL 5: U.S. Pat. No. 5,032,884

PTL 6: Japanese Patent Application Laid-Open No. HEI04-225282

PTL 7: U.S. Pat. No. 5,403,771

PTL 8: Japanese Patent Application Laid-Open No. 2009-76841

PTL 9: U.S. Patent Application Laid-Open No. 2009/0071539

### SUMMARY OF INVENTION

### Technical Problem

However, in the pin junction-type thin film solar cell of the related art, there was a problem in that the light conversion efficiency was low. The following two things are considered as the reasons thereof. The first reason is that, since the respective semiconductor layers are made of an amorphous phase, the carrier diffusion length is short, and carriers are liable to bond to each other again. The second reason is that a plurality of junction interfaces is present between semiconductor layers, and carriers are liable to bond to each other again in the junction interface.

The invention has been made in consideration of the problems of the related art, and provides a pin junction-type thin film solar cell having a higher conversion efficiency than a pin junction-type thin film solar cell of the related art, and a manufacturing method thereof.

### Solution to Problem

In order to achieve the above object, the thin film solar cell of the invention provides a thin film solar cell including a 60 μm or less-thick laminate including at least a first diffusion layer made of a semiconductor having a p-type or n-type conductivity, a film-forming layer made of a semiconductor having a lower conductivity than the first diffusion layer, and a second diffusion layer made of a semiconductor having a different polarity from the film-forming layer, in which the first diffusion layer and the second diffusion layer have impurities distributed in a film-thickness direction with a density gradient, the concentration of the impurities at an interface between the first diffusion layer and the film-forming layer is higher than the density of impurities at a surface of the first diffusion layer, and the concentration of the impurities at an interface between the second diffusion layer and the film-forming layer is higher than the density of impurities at a surface of the second diffusion layer.

### Advantageous Effects of Invention

As described above, according to the thin film solar cell and the manufacturing method thereof of the invention, it is possible to provide a thin film solar cell which can realize a higher photocurrent conversion efficiency (for example, 2.15 times or more in terms of cell conversion efficiency) than examples of the related art, and is constituted by pin junction-type thin film layers, and a manufacturing method thereof.

### BRIEF DESCRIPTION OF DRAWINGS

FIG. 1 is a schematic view showing a configuration of a laminate before an activation treatment for manufacturing a solar cell of Embodiment 1;

FIG. 2 is a schematic view showing a configuration of the solar cell of Embodiment 1;

FIG. 3 is a schematic view showing a configuration of a laminate before an activation treatment for manufacturing a solar cell of Embodiment 2;

FIG. 4 is a schematic view showing a configuration of the solar cell of Embodiment 2;

FIG. 5 is a schematic view showing a configuration of a laminate before an activation treatment for manufacturing a solar cell of Embodiment 3;

FIG. 6 is a schematic view showing a configuration of the solar cell of Embodiment 3;

FIG. 7 is a schematic view showing a configuration of a laminate before an activation treatment for manufacturing a solar cell of Embodiment 4;

FIG. 8 is a schematic view showing a configuration of the solar cell of Embodiment 4;

FIG. 9 is a table showing a manufacturing flowchart of the solar cells of Embodiments 1 to 4;

FIG. 10 is a table showing measurement results of conversion efficiencies of the solar cells of Embodiments 1 to 4;

FIG. 11 is a TEM observation image of Si crystalline phases in the solar cell of Embodiment 1;

FIG. 12A and 12B are views showing a relationship between a concentration of impurities and a depth from a surface of a diffusion layer in the solar cell of Embodiment 1 using SIMS; and

FIG. 13 is a schematic view showing a configuration of a solar cell of an example of the related art.

### DESCRIPTION OF EMBODIMENTS

Regarding the thin film solar cell of the invention

The thin film solar cell of the invention is a laminate including 1) a first diffusion layer, a film-forming layer, and a second diffusion layer, includes a laminate of a pin junction type, and preferably includes 2) a conductive base material or a base material on which a conductive layer is formed as well. The first diffusion layer is preferably in contact with the base material having a conductivity or the conductive layer formed on the base material. Furthermore, the thin film solar cell may include a surface electrode disposed on the surface of the second diffusion layer. The thickness of the laminate is preferably 60 or less, and more preferably 50 μm or less.

Examples of the base material having a conductivity include a metal plate and the like. In addition, the “base material on which the conductive layer is formed” generally includes a substrate made of an insulating material, such as glass or an organic resin, and a metal film or a transparent conductive film formed on the surface of the substrate. Examples of the metal or the transparent conductive film include tungsten (W), chromium (Cr), nickel (Ni), aluminum (Al), indium tin oxide (ITO), tin oxide (SnO), zirconium oxide (ZnO), and the like.

The laminate of the pin junction type is disposed on the base material having a conductivity or on the conductive layer of the base material.

The first diffusion layer, the film-forming layer, and the second diffusion layer are all made of a semiconductor material. Examples of the semiconductor material include silicon (Si), silicon-germanium (SiGe), germanium (Ge), silicon carbide (SiC), and the like. The semiconductor material that constitutes the first diffusion layer, the film-forming layer, and the second diffusion layer may be mutually the same or different.

All of the first diffusion layer, the film-forming layer, and the second diffusion layer preferably include a crystalline phase (or a polycrystalline phase), and preferably include the crystalline phase at 70% or more in terms of volume fraction. Crystalline grains that constitute the polycrystalline material in the respective layers preferably include crystalline grains having a grain diameter in a range of 1 nm to 20 nm.

The volume fractions of the crystalline phase in the first diffusion layer, the film-forming layer, and the second diffusion layer are measured through a peak separation analyzing method using spectrums obtained through Raman spectrometry. The volume of the amorphous phase corresponds to the area A of a broad waveform in the vicinity of 480 cm⁻¹ (Kaysers). The volume of the crystalline phase corresponds to the total area C of a peak waveform in the vicinity of approximately 500 cm⁻¹ to 525 cm⁻¹. The peak in the vicinity of 500 cm⁻¹ to 525 cm⁻¹ is frequently constituted of a plurality of peaks. Based on the areas obtained in the above manner, the volume fractions of the crystalline phase are obtained using “C/(A+C)*100 (%)”.

The grain diameter of the crystalline grains that constitute the crystalline phase is measured through transmission electron microscopy (TEM). Specifically, an image photographed at a magnification of approximately ten times is visually observed, and the grain size distribution is counted.

The first diffusion layer has a first conduction-type (p-type or n-type) conductivity. In addition, the second diffusion layer has a second conduction-type (n-type or p-type) conductivity. The first conduction type and the second conduction type are mutually different conduction types. That is, the second diffusion layer has the n-type conductivity as long as the first diffusion layer has the p-type conductivity; the second diffusion layer has the p-type conductivity as long as the first diffusion layer has the n-type conductivity.

Examples of the impurities included in the diffusion layers having the p-type conductivity include aluminum, boron, and the like. Examples of the impurities included in the diffusion layers having the n-type conductivity include phosphorous, nitrogen, arsenic, and the like.

The junction depth of any one or both of the first diffusion layer and the second diffusion layer is preferably 150 nm or less, and more preferably 100 nm or less. In addition, among the junction depths of the first diffusion layer and the second diffusion layer, the junction depth of at least one diffusion layer is preferably 100 nm or less, and the junction depth of the first diffusion layer (the diffusion layer in contact with the base material having a conductivity or the conductive layer formed on the base material) is preferably 100 nm or less.

Here, the “junction depth” refers to a depth from the surface of the diffusion layer to the interface between the diffusion layer and the film-forming layer. The interface between the diffusion layer and the film-forming layer refers to a surface at which the concentration of the impurities decreases to 1×10¹¹ atoms/cm³ from the concentration at the surface of the diffusion layer. The concentration of the impurities can be measured and analyzed through SIMS.

The first diffusion layer and the second diffusion layer can be obtained by diffusing the impurities from the surface of the semiconductor film and activating the diffused impurities. A plasma doping method is preferably used for introduction of the impurities.

In a case in which the impurities are introduced using the plasma doping method, examples of an introduction source of the p-type impurities include B₂H₆ (diborane), BF₃, BCl₃, and the like; examples of an introduction source of the n-type impurities include AsH₃ (arsin) gas, PH₃, POCl₃, PF₅, and the like.

In addition, the introduced impurities are preferably activated by carrying out a thermal treatment. Examples of the thermal treatment include use of an atmospheric-pressure plasma, flashlamp annealing, laser annealing, and the like. The above thermal treatments can rapidly heat the semiconductor film into which the impurities diffuse. Therefore, in a case in which the semiconductor film being heated is amorphous, it is possible to crystallize the semiconductor film.

The densities of the impurities at the surfaces of the first diffusion layer and the second diffusion layer are preferably 1×10²¹ atoms/cm³ to 3×10²² atoms/cm³. The density of the impurities can be measured and analyzed through SIMS. In addition, in a case in which the density of the impurities is high (in a high concentration range of approximately 5×10²⁰ atoms/cm³ to 5×10²² atoms/cm³), the density of the impurities can be measured and analyzed through XPS or AES.

In addition, the densities of the impurities in the first diffusion layer and the second diffusion layer have gradients along the thickness direction of the layers. Specifically, the density of the impurities at the surface of the first diffusion layer is high, and the concentration of the impurities in the first diffusion layer in the vicinity of the interface with the film-forming layer is low. Similarly, the density of the impurities at the surface of the second diffusion layer is high, and the concentration of the impurities in the second diffusion layer in the vicinity of the interface with the film-forming layer is low.

The film-forming layer may have the same conduction type as the first diffusion layer, but has a lower conductivity than the first diffusion layer. However, the film-forming layer is preferably an almost intrinsic semiconductor layer.

The deviation of the density of the impurities in the film-forming layer in the film thickness direction is preferably ±20% or less of the average value of the densities of the impurities in the film-forming layer.

The film-forming layer can be formed by crystallizing the semiconductor layer formed using a sputtering method, a vapor-deposition method, a CVD method, or the like. In the semiconductor layer formed using the sputtering method, a relatively large number of crystal defects are present. It was found that such a semiconductor layer is liable to be crystallized at a relatively low temperature. Therefore, the film-forming layer is preferably formed using the sputtering method. In addition, when the viewpoint of productivity such as the film-forming rate and the facility costs is taken into account, the semiconductor layer which serves as the film-forming layer is preferably formed using the vapor-deposition method or the sputtering method.

The formed semiconductor layer is preferably crystallized by carrying out a heating treatment on the semiconductor layer. Examples of the heating treatment include use of an atmospheric-pressure plasma, flashlamp annealing, laser annealing, and the like. However, in heating using flashlamp annealing, since desired infrared rays are radiated on the entire surface of the semiconductor layer at the same time, heat is liable to remain in the layer, and there is a problem in that the uniformity of the crystallization rate is liable to deteriorate, or the film is liable to be separated from the substrate. In addition, in heating using laser annealing, the radiation area is as small as several tens of μm², and there is a problem in the thermal treatment rate. Conversely, in heating using an atmospheric-pressure plasma, the radiation area is approximately 20 mm² to 50 mm², and is incomparably larger than the radiation area of laser annealing. Therefore, the heating treatment using an atmospheric-pressure plasma is more preferable.

The heating treatment for crystallizing the formed semiconductor layer and the heating treatment for activating the diffused impurities can be carried out in the same process.

A surface electrode is preferably disposed on the surface of the laminate. This is because electricity generated by the solar cell is collected. The surface electrode may be a metal film, a transparent conductive film, or the like. Examples of the metal film or the transparent conductive film include tungsten (W), chromium (Cr), nickel (Ni), aluminum (Al), indium tin oxide (ITO), tin oxide (SnO), zirconium oxide (ZnO), and the like.

The manufacturing method of a thin film solar cell of the invention may include, for example, 1) preparing a base material having a conductivity or a base material having a conductive layer formed on a surface, 2) introducing first conduction-type impurities to the surface of the base material having a conductivity or a surface of the conductive layer, 3) forming a semiconductor layer on the surface of the base material having a conductivity or the surface of the conductive layer using a sputtering method, a vapor deposition method, or a CVD method, 4) introducing second conduction-type impurities to the surface of the conductive layer, and 5) carrying out a thermal treatment on the semiconductor layer so as to activate the first conduction-type impurities and the second conduction-type impurities.

Hereinafter, embodiments of the invention will be described with reference to the accompanying drawings.

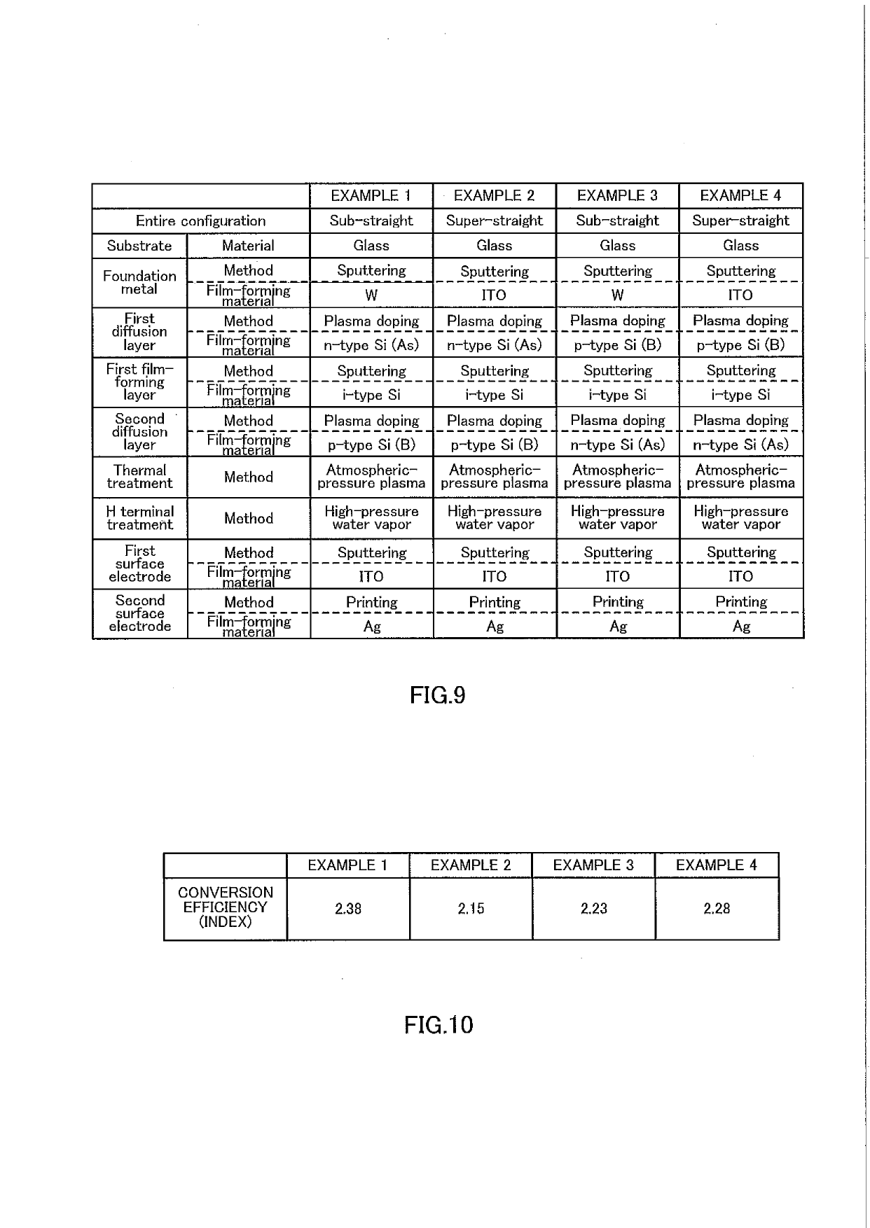

In the table in FIG. 9, the outline of the manufacturing flowchart of solar cells of Embodiments 1 to 4 was summarized. In addition, FIG. 10 shows the ratios of the photoelectric conversion efficiencies of the solar cells of Embodiments 1 to 4 to the photoelectric conversion efficiency of a thin film solar cell of an example of the related art. The basic configuration of the thin film solar cell of the example of the related art is shown in FIG. 13, and was manufactured using the method described in Example 1 of PTL 1 (Japanese Patent No. 3093504).

### Embodiment 1

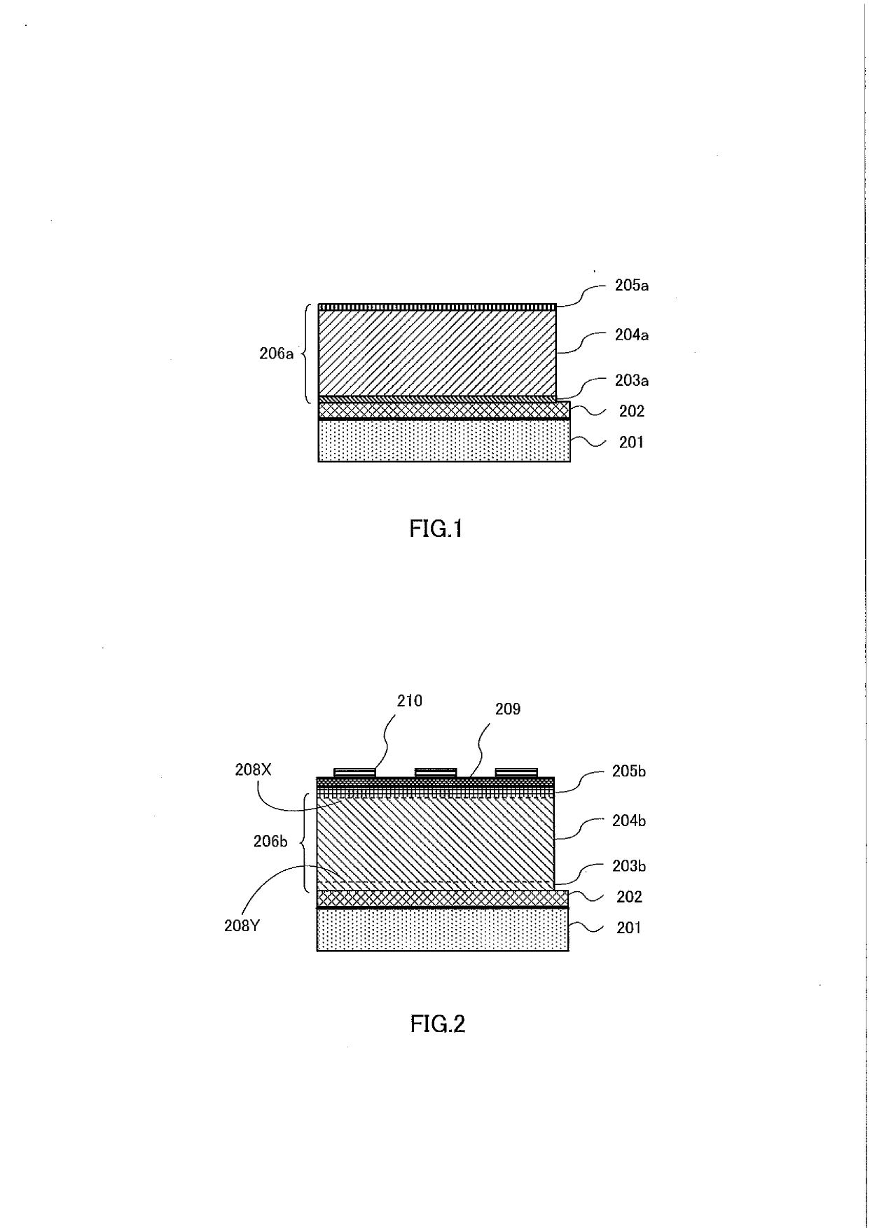

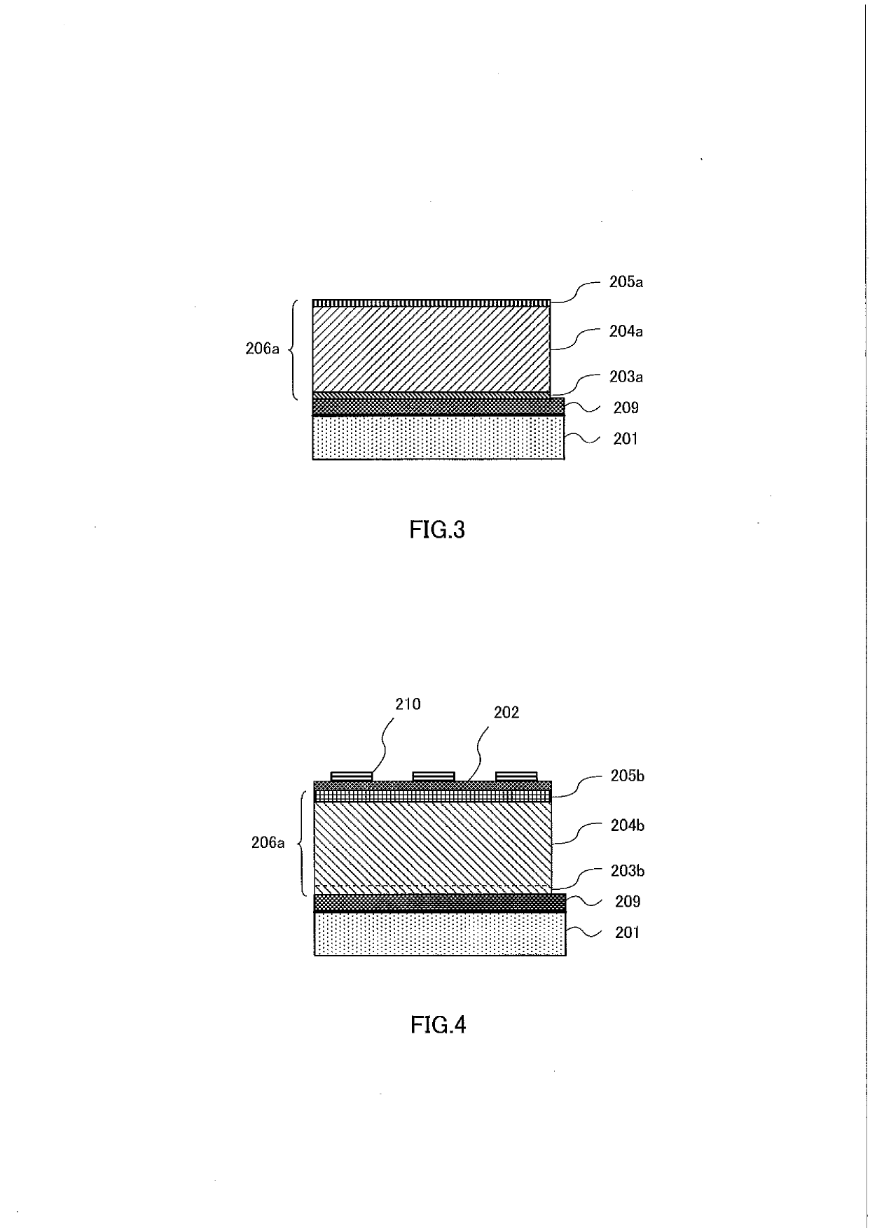

A thin film solar cell and a manufacturing method thereof of Embodiment 1 will be described with reference to FIG. 1 and FIG. 2. A thin film solar cell of Embodiment 1 has a sub-straight-type structure.

FIG. 2 shows the outline of the configuration of the thin film solar cell of Embodiment 1; heat-resistant glass substrate 201, tungsten (W) film 202 as a metal underlayer, laminate 206b, ITO film 209, and Ag electrode 210 are provided. Laminate 206b includes n-type Si diffusion layer 203b, i-type Si film-forming layer 204b, and p-type Si diffusion layer 205b.

In order to manufacture the thin film solar cell of Embodiment 1, firstly, laminate 206a shown in FIG. 1 is obtained. Specifically, heat-resistant glass substrate 201 having a thickness of approximately 400 μm to 1000 μm is injected into a first vacuum chamber (not shown). Tungsten film 202 having a thickness of approximately 100 nm to 2000 nm is formed as the metal underlayer on glass substrate 201 using the sputtering method.

Glass substrate 201 on which tungsten film 202 is formed is moved to a second vacuum chamber (not shown) while being held in a depressurized state. Next, while He, Ar and AsH₃ gasses are introduced, the pressure is adjusted in a range of 0.1 Pa to 100 Pa, and an RF electric power of approximately 0.1 W/cm² to 3 W/cm² is supplied, thereby forming As implantation area 203a on tungsten film 202 using a plasma doping method.

Next, glass substrate 201 having tungsten film 202 on which As implantation area 203a is formed is moved to a third vacuum chamber (not shown) while being held in a depressurized state. While Ar and H₂ atmospheric gasses are introduced, the pressure is adjusted in a range of 0.01 Pa to 2 Pa, and an RF electric power of approximately 1.5 W/cm² to 32 W/cm² is supplied, thereby forming i-type Si film-forming layer 204a using a sputtering method in which an i-type target of approximately 1×10¹² atoms/cm³ to 5×10¹⁵ atoms/cm³ is used. The thickness of i-type Si film-forming layer 204a is approximately 100 nm or more (preferably 1000 nm or more) and approximately 60 μm or less, preferably 10 μm or less, and more preferably 5 μm or less.

Furthermore, glass substrate 201 on which i-type Si film-forming layer 204a is formed is moved to a fourth vacuum chamber (not shown) while being held in a depressurized state. While He, Ar and B₂H₆ gasses are introduced, the pressure is adjusted in a range of 0.1 Pa to 100 Pa, and an RF electric power of approximately 0.1 W/cm² to 3 W/cm² is supplied, thereby forming B implantation area 205a on the i-type Si film-forming layer (i-type Si film-forming layer 204 which is the first film-forming layer). Laminate 206a is formed on glass substrate 201 in the above manner.

Next, laminate 206a formed on glass substrate 201 is extracted under atmospheric pressure, and is mounted on a heater at approximately 100° C. to 600° C. Under atmospheric pressure and in an Ar, N₂ and H₂ gasses atmosphere, an atmospheric-pressure plasma is generated in a DC torch-type plasma generating apparatus (not shown) to which an electric power of approximately 5 kW to 50 kW is supplied. The surface of laminate 206a is exposed to the generated plasma so as to form laminate 206b through crystallization or activation of impurities. Through the above steps, laminate 206b as schematically shown in FIG. 2 is formed.

Laminate 206b in FIG. 2 is different from laminate 206a in FIG. 1 in the following aspects.

1) i-type Si film-forming layer 204a is crystallized so as to form i-type Si film-forming layer 204b including a crystalline phase.

2) As in As implantation area 203a diffuses into i-type Si film-forming layer 204b in the depth direction in a range of approximately 1 nm to 100 nm, and is activated in Si phases so as to form n-type Si diffusion layer 203b which is the first diffusion layer.

3) B in B implantation area 205a diffuses into i-type Si film-forming layer 204b in the depth direction in a range of approximately 1 nm to 100 nm, and is activated in Si phases so as to form p-type Si diffusion layer 205b which is the second diffusion layer.

Next, laminate 206b on glass substrate 201 is moved to a high-pressure chamber. H₂O gas is introduced into the high-pressure chamber, the pressure is adjusted in a range of approximately 1.25 atmospheres to 10 atmospheres, and furthermore, the laminate is heated in a range of approximately 150° C. to 600° C., thereby carrying out a H₂O atmosphere treatment using a high-pressure water vapor method (not shown).

Next, laminate 206b on glass substrate 201 is moved to a fifth vacuum chamber (not shown). While the pressure is adjusted in a range of approximately 0.1 Pa to 10 Pa in an Ar gas atmosphere, an RF electric power of approximately 0.2 W/cm² to 20 W/cm² is supplied, thereby forming ITO film 209 using the sputtering method. The thickness of ITO film 209 is, for example, approximately 100 nm to 2000 nm.

Next, an Ag paste is coated in a pattern on ITO film 209 using a screen printing method, and organic substances in the Ag paste are dried in a range of approximately 50° C. to 250° C., thereby forming Ag electrode 210 as a second surface electrode. The thickness of Ag electrode 210 is approximately 1 μm to 50 μm, and the line width is preferably 100 μm to 1500 μm, but is not particularly limited. A thin film solar cell shown in FIG. 2 is manufactured in the above manner.

100 mW/cm² pseudo solar light was radiated on the thin film solar cell shown in FIG. 2 using a solar simulator, and the characteristics of the solar cell were measured. As a result, it could be confirmed that the solar cell has a conversion efficiency 2.38 times higher than that of the following thin film solar cell of an example of the related art.

### Embodiment 2

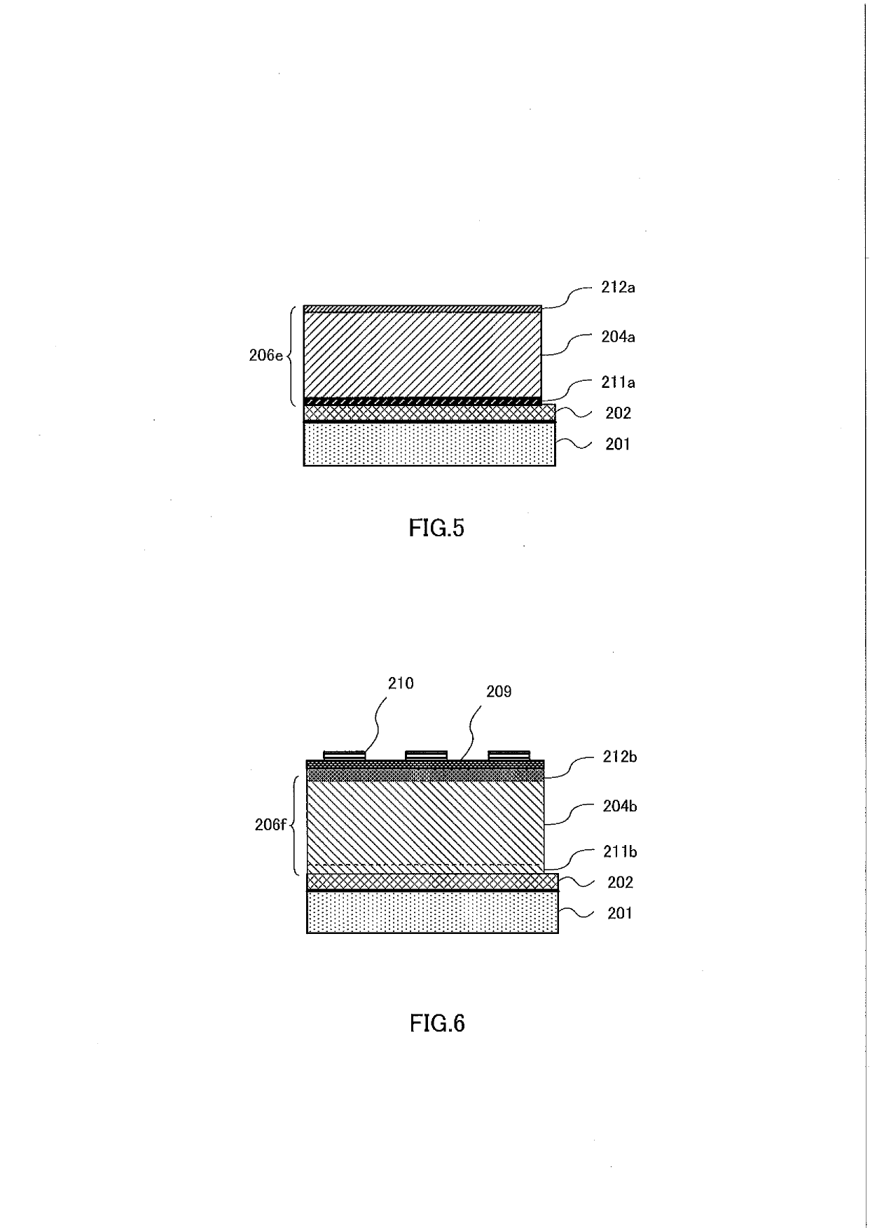

A thin film solar cell and a manufacturing method thereof of Embodiment 2 will be described with reference to FIG. 3 and FIG. 4. The thin film solar cell of Embodiment 2 has a super-straight-type structure. In FIG. 3 and FIG. 4, the same reference signs will be assigned for the same components as in FIG. 1 and FIG. 2, and description thereof will not be made.

FIG. 4 shows the outline of the configuration of the thin film solar cell of Embodiment 2. The configuration is the same as the configuration of the thin film solar cell of Embodiment 1 (refer to FIG. 2) except that ITO film 209 is used as the metal underlayer instead of tungsten film 202, and W film 202 is used as a first surface electrode instead of ITO film 209.

In order to manufacture the thin film solar cell of Embodiment 2, firstly, laminate 206a shown in FIG. 3 is obtained. The laminate was manufactured in the same manner as for laminate 206a of Embodiment 1 except that ITO film 209 (a thickness of approximately 100 nm to 2000 nm) was formed as the metal underlayer instead of tungsten film 202.

A plasma treatment is carried out on laminate 206a shown in FIG. 3 in the same manner as in Embodiment 1 so as to obtain laminate 206b shown in FIG. 4. However, a difference from Embodiment 1 is that tungsten film 202 (a thickness of approximately 100 nm to 2000 nm) is used as the first surface electrode instead of ITO film 209.

100 mW/em² pseudo solar light was radiated on the thin film solar cell shown in FIG. 4 using a solar simulator, and the characteristics of the solar cell were measured. As a result, it could be confirmed that the solar cell has a conversion efficiency 2.15 times higher than that of the following thin film solar cell of the example of the related art.

### Embodiment 3

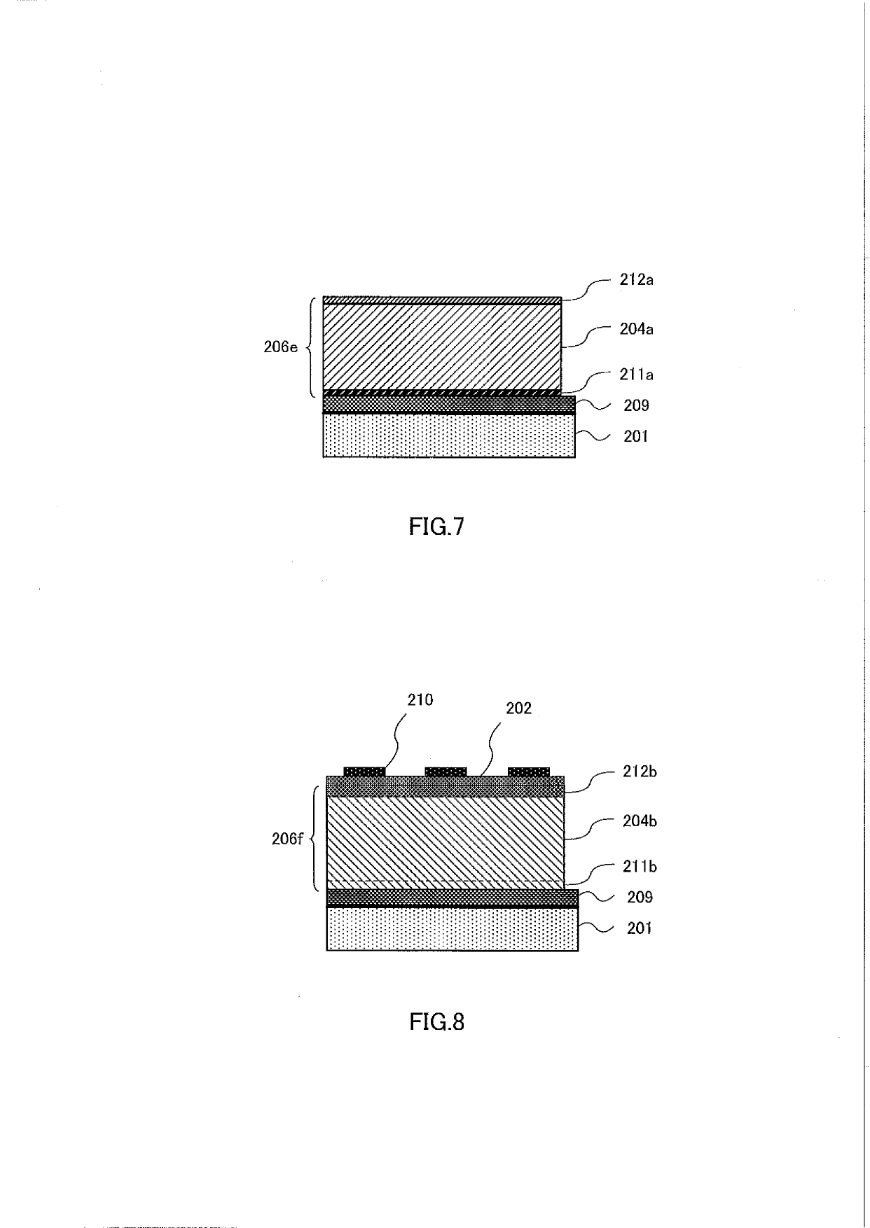

A thin film solar cell and a manufacturing method thereof of Embodiment 3 will be described with reference to FIG. 5 and FIG. 6. The thin film solar cell of Embodiment 3 has a sub-straight-type structure. In FIG. 5 and FIG. 6, the same reference signs will be assigned for the same components as in FIG. 1 and FIG. 2, and description thereof will not be made.

FIG. 6 shows the outline of the configuration of the thin film solar cell of Embodiment 3; heat-resistant glass substrate 201, tungsten (W) film 202 as the metal underlayer, laminate 206f, ITO film 209, and Ag electrode 210 are provided. Laminate 206b includes p-type Si diffusion layer 211bi-type Si film-forming layer 204b, and n-type Si diffusion layer 212b.

In order to manufacture the thin film solar cell of Embodiment 3, firstly, laminate 206e shown in FIG. 5 is obtained. Specifically, heat-resistant glass substrate 201 having a thickness of approximately 400 μm to 1000 μm is injected into the first vacuum chamber (not shown), and tungsten film 202 is formed as the metal underlayer on glass substrate 201 using the sputtering method. The thickness of tungsten film 202 may be approximately 100 nm to 2000 nm.

Glass substrate 201 on which tungsten film 202 is formed is moved to the second vacuum chamber (not shown) while being held in a depressurized state. Next, while He, Ar, and B₂H₆ gasses are introduced, the pressure is adjusted in a range of 0.1 Pa to 100 Pa, and an RF electric power of approximately 0.1 W/cm² to 3 W/cm² is supplied, thereby forming B implantation area 211a on tungsten film 202 using the plasma doping method.

Next, glass substrate 201 having tungsten film 202 on which B implantation area 211a is formed is moved to the third vacuum chamber (not shown) while being held in a depressurized state. While Ar and H₂ atmospheric gasses are introduced, the pressure is adjusted in a range of 0.01 Pa to 2 Pa, and an RF electric power of approximately 1.5 W/cm² to 32 W/cm² is supplied, thereby forming i-type Si film-forming layer 204a using a sputtering method in which an i-type Si of approximately 1×10¹² atoms/cm³ to 5×10¹⁵ atoms/cm³ is used as a target. The thickness of i-type Si film-forming layer 204a is not particularly limited, but is approximately 100 nm or more (preferably 1000 nm or more) and approximately 60 μm or less, preferably 10 μm or less, and more preferably 5 μm or less.

Next, glass substrate 201 on which i-type Si film-forming layer 204a is formed is moved to the fourth vacuum chamber (not shown) while being held in a depressurized state. While He, Ar and AsH₃ (arsine) gasses are introduced, the pressure is adjusted in a range of 0.1 Pa to 100 Pa, and an RF electric power of approximately 0.1 W/cm² to 3 W/cm² is supplied, thereby forming As implantation area 212a on i-type Si film-forming layer 204a using the plasma doping method. Laminate 206e is formed on glass substrate 201 in the above manner.

Next, laminate 206e is extracted under the atmospheric pressure, and is mounted on a heater at approximately 100° C. to 600° C. Under the atmospheric pressure and an Ar, N₂ and H₂ gasses atmosphere, an atmospheric-pressure plasma is generated in a DC torch-type plasma generating apparatus (not shown) to which an electric power of approximately 5 kW to 50 kW is supplied. The surface of laminate 206e was exposed to the generated plasma so as to induce crystallization or activation of impurities. Laminate 206f was formed in the above manner.

Laminate 206f in FIG. 6 is different from laminate 206e in FIG. 5 in the following aspects.

1) i-type Si film-forming layer 204a is crystallized so as to form i-type Si film-forming layer 204b which is the first diffusion layer.

2) B in B implantation area 211 a diffuses into i-type Si film-forming layer 204b in the thickness direction in a range of approximately 1 nm to 100 nm, and is activated in Si phases so as to form p-type Si diffusion layer 211b which is the first diffusion layer.

3) As in As implantation area 212b diffuses into i-type Si film-forming layer 204b in the thickness direction in a range of approximately 1 nm to 100 nm, and is activated in Si phases so as to form n-type Si diffusion layer 212b which is the second diffusion layer.

Furthermore, laminate 206f on glass substrate 201 is moved to the high-pressure chamber. H₂O gas is introduced into the high-pressure chamber, the pressure is adjusted in a range of approximately 1.25 atmospheres to 10 atmospheres, and furthermore, the laminate is heated in a range of approximately 150° C. to 600° C., thereby carrying out a H₂O atmosphere treatment on laminate 206f using a high-pressure water vapor method (not shown).

Next, laminate 206f on glass substrate 201 is moved to the fifth vacuum chamber (not shown). While the pressure was adjusted in a range of approximately 0.1 Pa to 10 Pa in an Ar gas atmosphere, an RF electric power of approximately 0.2 W/cm² to 20 W/cm² was supplied, thereby forming ITO film 209 as the first surface electrode using the sputtering method. The thickness of ITO film 209 is preferably approximately 100 nm to 2000 nm, but is not particularly limited.

Next, an Ag paste is coated in a pattern on ITO film 209 using a screen printing method, and organic substances in the Ag paste are dried in a range of approximately 50° C. to 250° C., thereby forming Ag electrode 210 as the second surface electrode. The height of Ag electrode 210 is approximately 1 μm to 50 μm, and the line width is preferably 100 μm to 1500 μm, but is not particularly limited. A thin film solar cell shown in FIG. 6 is manufactured in the above manner.

100 mW/cm² pseudo solar light was radiated on the thin film solar cell shown in FIG. 6 using a solar simulator, and the characteristics of the solar cell were measured. As a result, it could be confirmed that the solar cell has a conversion efficiency 2.23 times higher than that of the following thin film solar cell of the example of the related art.

### Embodiment 4

A thin film solar cell and a manufacturing method thereof of Embodiment 4 will be described with reference to FIG. 7 and FIG. 8. The thin film solar cell of Embodiment 4 has a sub-straight-type structure. In FIG. 7 and FIG. 8, the same reference signs will be assigned for the same components as in FIG. 5 and FIG. 6, and description thereof will not be made.

FIG. 8 shows the outline of the configuration of the thin film solar cell of Embodiment 4. The configuration is the same as the configuration of the thin film solar cell of Embodiment 3 (refer to FIG. 6) except that ITO film 209 is used as the metal underlayer instead of tungsten film 202, and tungsten film 202 is used as a first surface electrode instead of ITO film 209.

In order to manufacture the thin film solar cell of Embodiment 4, firstly, laminate 206e shown in FIG. 7 is obtained. The laminate was manufactured in the same manner as for laminate 206e of Embodiment 3 except that ITO film 209 (a thickness of approximately 100 nm to 2000 nm) was formed as the metal underlayer instead of tungsten film 202.

A plasma treatment is carried out on laminate 206e shown in FIG. 7 in the same manner as in Embodiment 3 so as to obtain laminate 206f shown in FIG. 8. However, a difference from Embodiment 3 is that tungsten film 202 (a thickness of approximately 100 nm to 2000 nm) is used as the first surface electrode instead of ITO film 209.

Next, Ag electrode 210 is formed on tungsten (W) film 202 in the same manner as in Embodiment 3 so as to obtain a thin film solar cell shown in FIG. 8.

100 mW/cm² pseudo solar light was radiated on the thin film solar cell shown in FIG. 8 using a solar simulator, and the characteristics of the solar cell were measured. As a result, it could be confirmed that the solar cell has a conversion efficiency 2.28 times higher than that of the following thin film solar cell of the example of the related art.

The reasons why the conversion efficiency of the thin film solar cell of the invention improves compared to the conversion efficiency of the thin film solar cell of the example of the related art are not limited, and can be considered to be, for example, as follows. It is needless to say that the reasons why the conversion efficiency improves are not limited thereto.

The first reason is that, while the respective layers in the thin film solar cell of the example of the related art are amorphous phases, the semiconductor layers in the thin film solar cell of the invention can be made to have polycrystalline phases in which a mixture of crystalline grains having grain diameters of several nm to approximately 800 nm is present. It is considered that the carrier diffusion length is larger in polycrystalline phases than in amorphous phases, and it becomes difficult for carriers to bond again to each other.

The second reason is that, while, in the thin film solar cell of the example of the related art, the amorphous phase formed using a CVD method is maintained as amorphous, in the thin film solar cell of the invention, the amorphous phase turns into a phase state which is close to a substantially liquid phase, and then is crystallized. The crystallization prevents clear existence of interfaces between the semiconductor layers which are observed in the thin film solar cell of the example of the related art. In the interfaces between the layers, there are many crystal defects, and carriers easily bond to each other again. It is considered that prevention of the existence of interfaces between the semiconductor layers suppresses re-bonding of carriers.

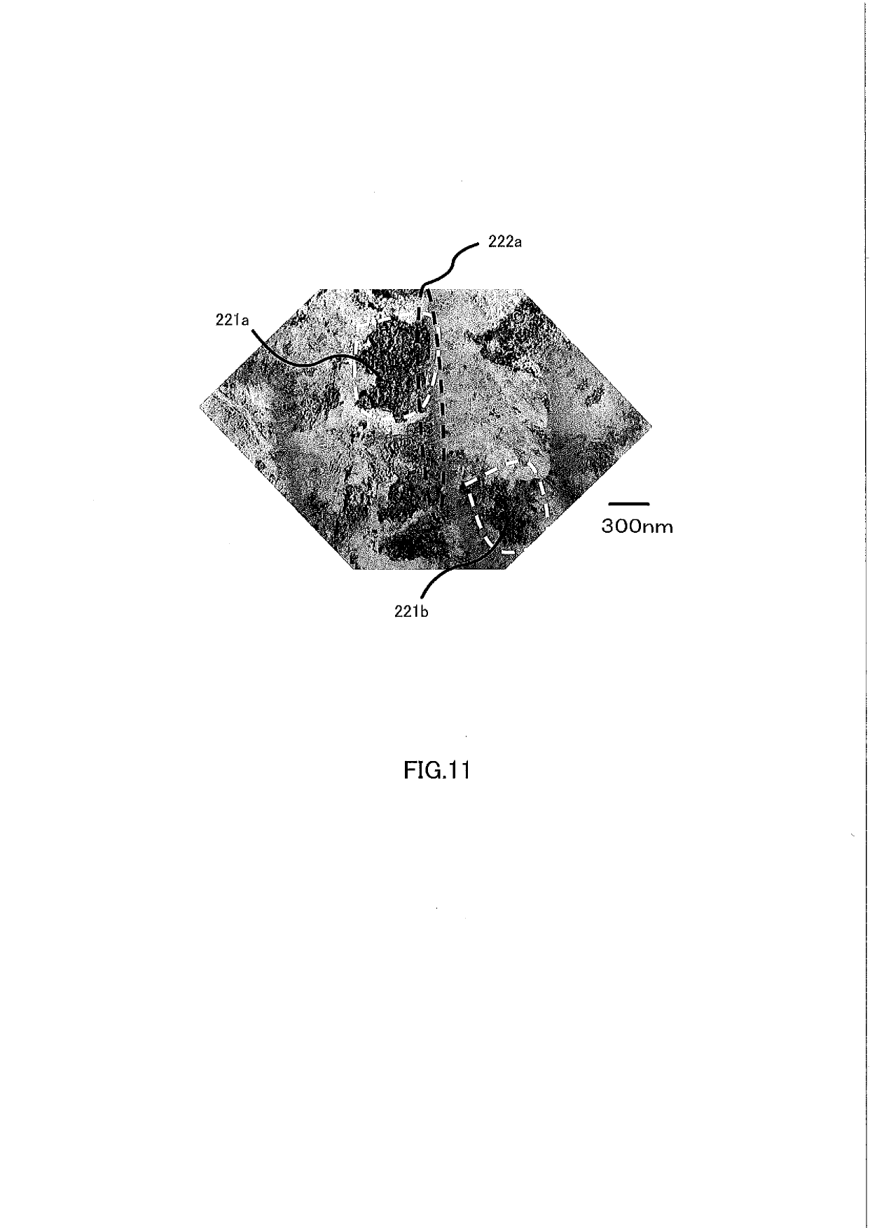

FIG. 11 shows a light field image of a cross-section of a Si semiconductor layer made of the laminate (n-type Si diffusion layer 203b, i-type Si film-forming layer 204b, and p-type Si diffusion layer 205b) in the thin film solar cell manufactured in Embodiment 1 photographed using TEM. The field image of FIG. 11 shows the entire laminate (the first diffusion layer, the film-forming layer, and the second diffusion layer) in the thickness direction. In the light field image of FIG. 11, crystalline grains 221a and 221b having a crystalline grain diameter of approximately 400 nm to 800 nm and aggregate portion 222a of the microcrystalline grains having grain diameters of several nm to approximately 10 nm can be observed. As such, it is found that n-type Si diffusion layer 203b, i-type Si film-forming layer 204b, and p-type Si diffusion layer 205b are crystalline phases including crystalline grains.

The crystallization rate of the laminate in the thin film solar cell of the invention was measured using Raman spectroscopy. Specifically, the crystallization rate was measured from rates of areas of 520 cm⁻¹ and 500 cm⁻¹ to an area of 470 cm⁻¹. As a result, it could be confirmed that the crystallization rate of the laminate immediately after the film formation using the sputtering method was 0% (amorphous phase), and the crystallization rate of the laminate after the laminate was crystallized through the treatment using the atmospheric-pressure plasma method was 80% or more.

Furthermore, as shown in the TEM image of FIG. 11, it could be confirmed that it was not possible to clearly observe interface 208X between p-type Si diffusion layer 205b and i-type Si film-forming layer 204b and interface 208Y between n-type Si diffusion layer 203b and i-type Si film-forming layer 204b (refer to FIG. 2). As such, it is considered that it becomes difficult to differentiate the phase in the diffusion layers and the phase in the film-forming layer, and therefore re-bonding of carriers is suppressed.

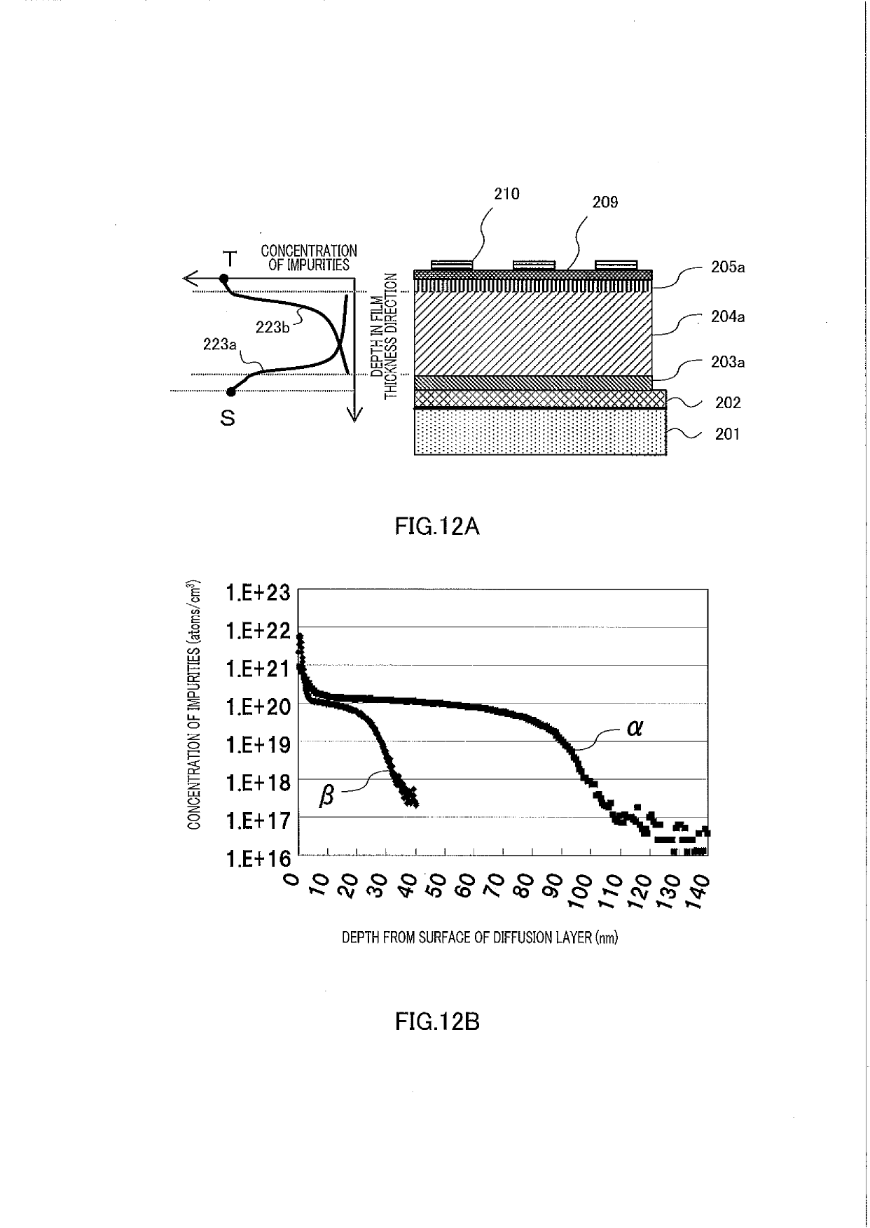

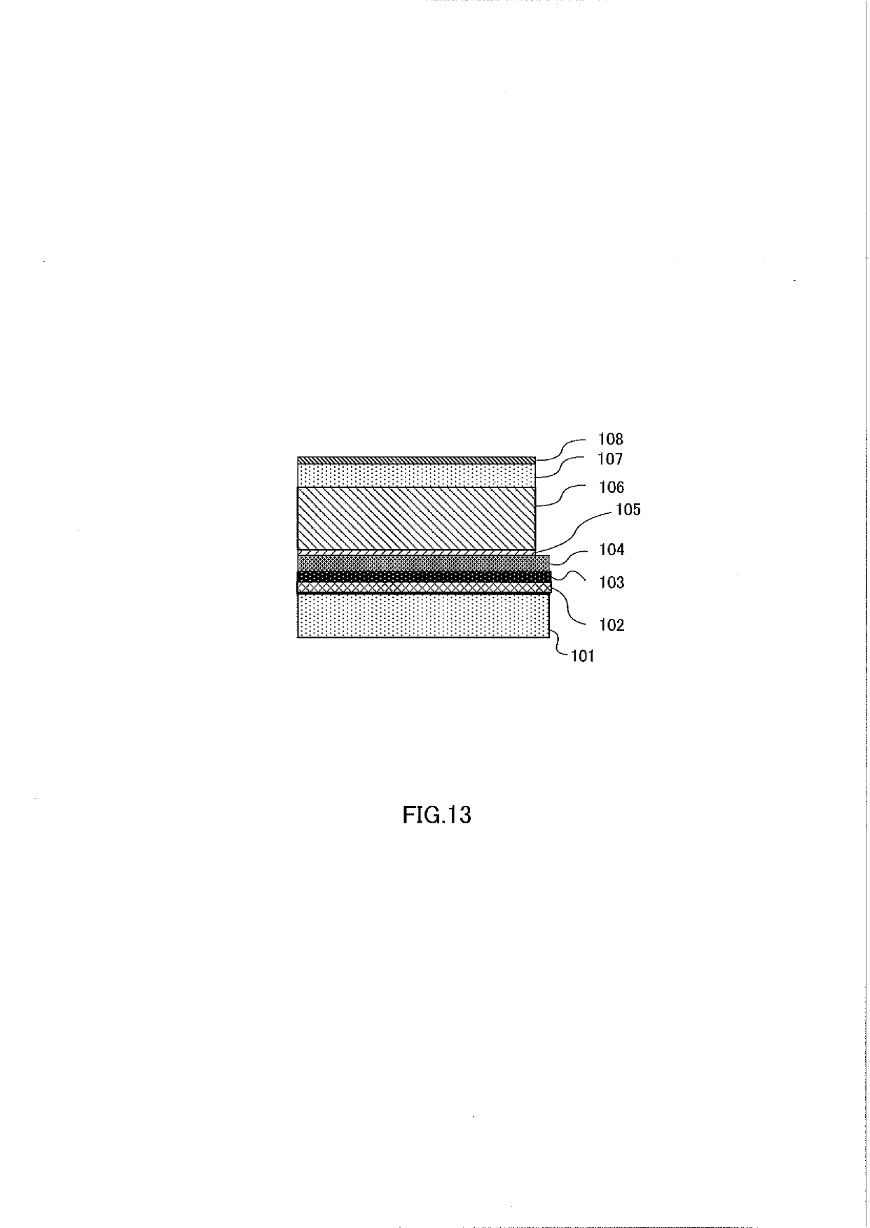

Next, the profile of the concentration of the impurities in the laminate (n-type Si diffusion layer 203b, i-type Si film-forming layer 204b, and p-type Si diffusion layer 205b) in the thin film solar cell of Embodiment 1 in the thickness direction was measured through SIMS. The results are shown in FIG. 12A. In FIG. 12A, curved line 223b indicates the density of B (boron element), and curved line 223a indicates the density of As (arsenic element).

As shown in FIG. 12A, the number density of B (boron) at surface T of second diffusion layer 205a of the laminate was 1×10²¹ atoms/cm³, the number density of B decreased in a gradient manner in the thickness direction of the layer, and the number density of B (boron) at the interface between the film-forming layer and the second diffusion layer was 1×10¹⁷ atoms/cm³.

In addition, the number density of As (arsenic) at surface S of first diffusion layer 203a of the laminate was 1×10²¹ atoms/cm³ or more, the number density of As decreased in a gradient manner in the thickness direction of the layer, and the number density of As at the interface between the film-forming layer and the first diffusion layer was 1×10¹⁷ atoms/cm³.

The graph of FIG. 12B shows measurement data (curved line a) showing the relationship between the number density of B (boron) in the second diffusion layer in the laminate and the depth direction, and measurement data (curved line β) showing the relationship between the number density of As (arsenic) in the first diffusion layer in the laminate and the depth direction. It is found that, in all data, the concentrations of the impurities at the surfaces of the diffusion layers were 1×10²¹ atoms/cm³ to 1022 atoms/cm³, and the concentrations of the impurities gradually decreased up to the interface between the diffusion layer and the film-forming layer (the surface at which the concentration of the impurities becomes 1×10¹⁷ atoms/cm³).

### Industrial Applicability

The thin film solar cell constituted by the film-forming layer and the diffusion layers and the manufacturing method of the invention can provide a thin film solar cell which is constituted by a pin junction-type thin film layer and which can improve the cell conversion efficiency by 2.15 times or more compared to an example of the related art. The thin film solar cell is also applicable to use in energy fields and battery fields of thin film solar cells.

### Reference Signs List

201 Glass Substrate

202 W Film

203a As Implantation Area

212a As implantation Area

212b As implantation Area

204 i-type si film-forming Layer Which is a Film-forming Layer

205a B Implantation Area

211a B Implantation Area

206a Laminate

206b Laminate

206e Laminate

206f Laminate

208X Interface

208Y Interface

1. A thin film solar cell comprising:
a 60 μm or less-thick laminate including at least a first diffusion layer made of a semiconductor having a p-type or n-type conductivity; a film-forming layer made of a semiconductor having a lower conductivity than the first diffusion layer; and a second diffusion layer made of a semiconductor having a different polarity from the film-forming layer, wherein
the first diffusion layer and the second diffusion layer have impurities distributed in a film-thickness direction with a density gradient;
the density of the impurities at an interface between the first diffusion layer and the film-forming layer is higher than the concentration of the impurities at a surface of the first diffusion layer; and
the density of the impurities at an interface between the second diffusion layer and the film-forming layer is higher than the concentration of the impurities at a surface of the second diffusion layer.

2. The thin film solar cell according to claim 1, wherein:
the first diffusion layer is in contact with a substrate having a conductivity or a conductive layer formed on the substrate.

3. The thin film solar cell according to claim I, which is a pin junction-type solar cell wherein:
the laminate is a pin junction-type;
the first diffusion layer has an n-type conductivity, the film-forming layer has a conductivity almost as low as intrinsic, and the second diffusion layer has a p-type conductivity; or
the first diffusion layer has a p-type conductivity, the film-forming layer has a conductivity almost as low as intrinsic, and the second diffusion layer has an n-type conductivity.

4. The thin film solar cell according to claim 1, wherein:
the first diffusion layer, the film-forming layer, and the second diffusion layer are made of silicon, and include a crystalline phase at 70% or more in terms of volume fraction.

5. The thin film solar cell according to claim 4, wherein:
the crystalline phase is made of a polycrystalline material, and crystalline grains having at least a grain diameter in a range of 1 nm to 200 nm are present in the layers.

6. The thin film solar cell according to claim 1, wherein:
the first diffusion layer and the second diffusion layer have a junction depth of 150 nm or less.

7. The thin film solar cell according to claim 1, wherein:
impurities of aluminum or boron are introduced into the first diffusion layer or the second diffusion layer having the p-type conductivity; and
impurities of phosphorous, nitrogen, or arsenic are introduced into the first diffusion layer or the second diffusion layer having the n-type conductivity,

8. The thin film solar cell according to claim 1, wherein:
the densities of the impurities at the surfaces of the first diffusion layer and the second diffusion layer are 1×10²¹ atoms/cm³ to 3×10²² atoms/cm³.

9. The thin film solar cell according to claim 1, wherein:
the deviation of the densities of the impurities in the film-thickness direction of the film-forming layer is ±20% or less of an average value of the densities of the impurities of the film-forming layer.

10. A manufacturing method of a thin film solar cell having a 60 μm or less-thick laminate made of at least three layers, comprising:
forming a first diffusion layer made of a semiconductor having a p-type or n-type conductivity on a base material having a conductivity or a conductive layer which is formed on a base material;
forming a film-forming layer made of a semiconductor having a lower conductivity than the first diffusion layer on the first diffusion layer; and
forming a second diffusion layer made of a semiconductor having a different polarity from the first diffusion layer on the film-forming layer;
wherein the first diffusion layer and the second diffusion layer have impurities distributed in a film-thickness direction with a density gradient;
the density of the impurities at an interface between the first diffusion layer and the film-forming layer is higher than the concentration of the impurities at a surface of the first diffusion layer; and
the density of the impurities at an interface between the second diffusion layer and the film-forming layer is higher than the concentration of the impurities at a surface of the second diffusion layer.

11. The manufacturing method of a thin film solar cell according to claim 10, wherein:
the laminate has a pin junction-type;
the first diffusion layer has an n-type conductivity, the film-forming layer has a conductivity almost as low as intrinsic, and the second diffusion layer has a p-type conductivity; or
the first diffusion layer has a p-type conductivity, the film-forming layer has a conductivity almost as low as intrinsic, and the second diffusion layer has an n-type conductivity.

12. The manufacturing method of a thin film solar cell according to claim 10, further comprising:
preparing a base material having a conductivity or a base material having a conductive layer formed on a surface thereof;
introducing first conduction-type impurities to the surface of the base material having a conductivity or a surface of the conductive layer;
forming a semiconductor layer on the surface of the base material having a conductivity or the surface of the conductive layer using a sputtering method, a vapor deposition method, or a CVD method;
introducing second conduction-type impurities to the surface of the conductive layer; and
carrying out a thermal treatment on the semiconductor layer so as to activate the first conduction-type impurities and the second conduction-type impurities.

13. The manufacturing method of a thin film solar cell according to claim 12, wherein:
the semiconductor layer is formed using the sputtering method.

14. The manufacturing method of a thin film solar cell according to claim 12, wherein:
the first conduction-type impurities or the second conduction-type impurities are introduced using a plasma doping method.

15. The manufacturing method of a thin film solar cell according to claim 12, wherein:
the thermal treatment on the semiconductor layer includes rapid heating using an atmospheric-pressure plasma, flashlamp annealing, or laser annealing; and
the first conduction-type impurities and the second conduction-type impurities are activated so as to crystallize the semiconductor layer.
